(19) United States
(12) Patent Application Publication
(10) Pub. No.: US 2026/0211130 A1
(43) Pub. Date: Jul. 23, 2026

(54) Multifunctional Radiation Detector

(71) Applicant: RADIACODE LTD, Limassol (CY)

(72) Inventors: Iurii ZOBNIN, Souni (CY); Sergei SHCHEKOCHIKHIN, Limassol (CY)

(73) Assignee: RADIACODE LTD, Limassol (CY)

(21) Appl. No.: 19/275,945

(22) Filed: Jul. 21, 2025

Related U.S. Application Data
(60) Provisional application No. 63/674,718, filed on Jul. 23, 2024.

(51) Int. Cl. G01T 1/202; G01T 1/208; G01T 7/12; H05K 5/00

(52) U.S. Cl. CPC G01T 1/202; G01T 1/208; G01T 7/12; H05K 5/0018; H05K 5/0086

(57) ABSTRACT

A radiation detector configured to detect, analyze and measure a broad spectrum of ionizing radiation energies includes a housing having a hollow interior, a display opening and one or more secondary openings, and a processing board enclosed within the interior of the housing. The processing board includes a scintillation detector having a cube-shaped scintillation crystal and a flexible PCB. A first end of the flexible PCB includes a solid-state silicon photomultiplier that is optically connected to the scintillation crystal and a second end of the flexible PCB is communicatively connected to the processing board. The processing board further includes a microprocessor configured to process electrical pulses received from the silicon photomultiplier, a display having a display flexible PCB communicatively connected to the processing board and one or more operating buttons for selectively operating the radiation detector.

### CROSS-REFERENCE TO RELATED APPLICATION

The present application claims priority of U.S. provisional application Ser. No. 63/674,718, filed Jul. 23, 2024, which is hereby incorporated herein by reference in its entirety.

### FIELD OF THE INVENTION

The present invention relates in general to a radiation detector, and more particularly to a multifunctional detector of nuclear radiation.

### BACKGROUND OF THE INVENTION

A detector of radiation is generally known as a device designed to detect and preferably measure different types of radiation emitted from radioactive materials or sources. These detectors are crucial for various applications, including nuclear power plants, medical diagnostics and treatments, environmental monitoring, and scientific research. It is further known that there are at least several types of radiation detectors, one of those types being scintillation detectors. These detectors use materials that emit light (scintillate) when radiation interacts with them. The emitted light is then converted into an electrical signal that can be measured and analyzed.

It is further known that scintillation detectors work by converting the energy of incoming gamma rays into flashes of light (scintillations) within a scintillation crystal (e.g., sodium iodide or cesium iodide). Photomultiplier tubes (PMTs) or other light-sensitive detectors then convert these flashes of light into electrical pulses. Scintillation detectors are widely used in radiation monitoring, environmental monitoring, nuclear medicine, health physics, and security applications (e.g., border security and cargo inspection). They are versatile and can be used in handheld instruments as well as larger systems.

Existing scintillation detectors, while versatile and widely used, have several shortcomings or limitations compared to other types of radiation detectors. For example, many scintillation detectors currently available in the market lack multifunctionality, versatility and can be sensitive to temperature variations, which can affect their performance and stability over time. High-performance scintillation detectors, in turn, are typically larger and heavier compared to simpler radiation detectors impacting their ease of deployment and use in certain field applications. Additionally, high-performance scintillation detectors can still be relatively costly, especially those designed for specific scientific or industrial applications. Thus, there is a need for a portable, low-cost, reliable, easy-to-operate and multifunctional radiation detector that utilizes scintillation technology.

### SUMMARY OF THE INVENTION

The following presents a simplified summary in order to provide a basic understanding of some aspects of the invention. The summary is not an extensive overview of the invention. It is neither intended to identify key or critical elements of the invention nor to delineate the scope of the invention. The following summary merely presents some concepts of the invention in a simplified form as a prelude to the description below.

The multifunctional radiation detector of the present disclosure aims to overcome at least the above-described limitations by providing a highly compact and portable, multifunctional and reliable radiation detector that utilizes scintillation technology, yet is not as sensitive to temperature variations and highly effective in detecting gamma, high energy Beta, and continuous X-rays.

The multifunctional radiation detector of the present disclosure includes a sealed container having a thallium doped cesium iodide crystal that is formed as a cube, a solid-state silicon photomultiplier in optical communication with the crystal, an optical interface disposed between the thallium doped cesium iodide crystal and the solid-state silicon photomultiplier, and a high-speed analog-digital circuit module configured for processing electrical pulses received from the solid-state silicon photomultiplier. The photomultiplier is configured to convert light when emitted from the crystal into a stream of electrons and the high-speed analog-digital circuit module is configured to output a value that is proportional to an energy of ionizing particles that entered the thallium doped cesium iodide crystal.

According to one form of the present invention, a radiation detector that is configured to detect, analyze and measure a broad spectrum of ionizing radiation energies includes a housing having a hollow interior, a display opening and one or more secondary openings, and a processing board enclosed within the interior of the housing. The processing board includes a scintillation detector having a cube-shaped scintillation crystal and a flexible PCB. A first end of the flexible PCB includes a solid-state silicon photomultiplier that is optically connected to the scintillation crystal and a second end of the flexible PCB is communicatively connected to the processing board. The processing board further includes a microprocessor configured to process electrical pulses received from the silicon photomultiplier, a display having a display flexible PCB communicatively connected to the processing board and one or more operating buttons for selectively operating the radiation detector.

According to another form of the present invention, a radiation detector having a housing with a hollow interior, a display opening and one or more secondary openings, and a processing board enclosed within the interior of the housing, the radiation detector incudes a scintillation detector having a cube-shaped scintillation crystal and a flexible printed circuit board (PCB). The first end of the flexible PCB includes a reinforcing member having two opposing sides. The first side of the two opposing sides includes an attachment member and the second side includes a solid-state silicon photomultiplier and a thermo-sensor. The silicon photomultiplier is optically connected to the scintillation crystal, and the second end of the flexible PCB is communicatively connected to the processing board. The radiation detector further includes a microprocessor having an embedded flash memory with firmware and computer-readable instructions stored thereon. The microprocessor is configured to process electrical pulses received from the silicon photomultiplier and calculate a value that is proportional to an energy of ionizing particles detected by the scintillation crystal. The radiation detector further includes a display having a display flexible PCB communicatively connected to the processing board, the display is configured to be received within the display opening of the housing and configured to display the value calculated by the microprocessor. The radiation detector further includes one or more operating buttons for selectively operating the radiation detector, the one or more operating buttons are configured to be received within respective one or more secondary openings in the housing.

Aspects of the present disclosure provide a radiation detector that is configured to detect, analyze and measure a broad spectrum of ionizing radiation energies and that is multifunctional, portable and compact, light and cost effective while software-enabled and capable of distinguishing between gamma rays of slightly different energies to help detect, measure, and interpret detailed spectral information. These and other objects, advantages, purposes and features of the present invention will become apparent upon review of the following specification in conjunction with the drawings.

### BRIEF DESCRIPTION OF THE DRAWINGS

The drawings are not necessarily to scale and, in some instances, proportions have been exaggerated in order to more clearly depict certain features of the invention.

FIG. 1 is an exploded perspective view a radiation detector, in accordance with an embodiment of the present invention;

FIG. 2A is a front elevation view of a processing board of the radiation detector of FIG. 1, shown with a scintillation detector and a display;

FIG. 2B is a back elevation view of the processing board of the radiation detector of FIG. 1, shown with the scintillation detector and the display;

FIG. 3A is a front elevation view of a digital display of the radiation detector of FIG. 1;

FIG. 3B is a back elevation view of the digital display of the radiation detector of FIG. 1;

FIG. 4A is a perspective view of a scintillation detector of the radiation detector of FIG. 1, shown having a container and a flexible printed circuit board;

FIG. 4B is an exploded perspective view of the scintillation detector of FIG. 4A;

FIG. 4C is a back elevation view of the flexible printed circuit board of the scintillation detector of FIG. 4A; and

FIG. 4D is a front elevation view of the flexible printed circuit board of the scintillation detector of FIG. 4A.

### DETAILED DESCRIPTION OF PREFERRED EMBODIMENTS

Embodiments of the present invention will now be described more fully hereinafter with reference to the accompanying drawings, in which some, but not all, embodiments of the invention are shown. Indeed, the invention may be embodied in many different forms and should not be construed as limited to the embodiments set forth herein; rather, these embodiments are provided so that this disclosure will satisfy applicable legal requirements. Like numbers refer to like elements throughout. Throughout this disclosure, unless the context dictates otherwise, the word “comprise” or variations such as “comprises” or “comprising,” is understood to mean “includes, but is not limited to” such that other elements that are not explicitly mentioned may also be included. Further, any terms expressed in the singular form herein are meant to also include the plural form and vice versa, unless explicitly stated otherwise. Also, as used herein, the term “a” and/or “an” shall mean “one or more,” even though the phrase “one or more” is also used herein.

In the following, a more detailed description of exemplarily embodiments of the present disclosure will be provided. The multifunctional detector of nuclear radiation of the present disclosure is provided as a scintillation detector that is configured to assess or determine the ambient background radiation and the level of radiation emitted by a substance, object, or surface, such as for example a building material, an antique, a vehicle, soil, etc. Also, the scintillation detector of the present disclosure is able to visualize the energy spectrum of the absorbed radiation-for a subsequent independent determination of the substance (isotope) that is the source of radiation.

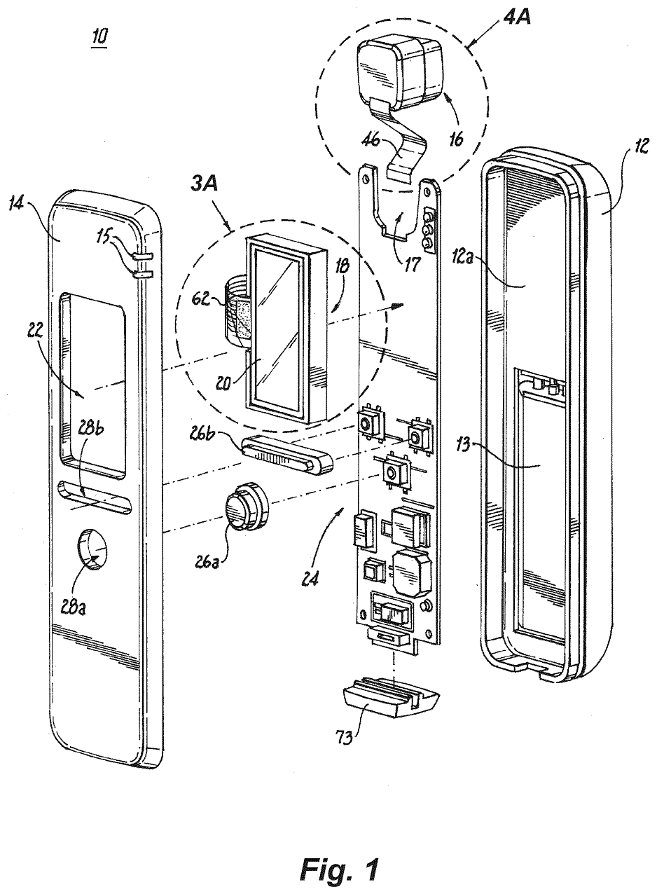

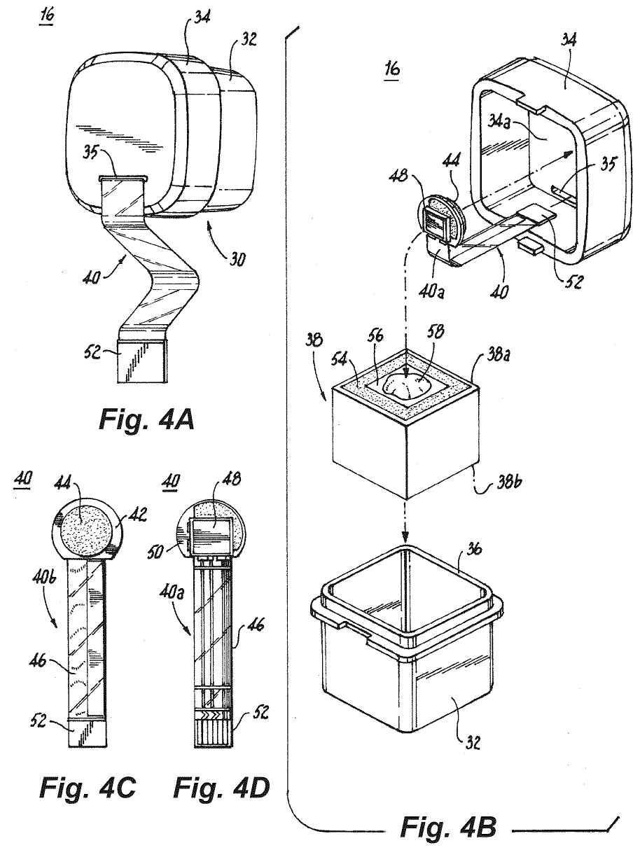

Referring now to the drawings and the illustrative embodiments depicted therein, a radiation detector 10 of the present disclosure, as shown in FIG. 1, includes a housing 12 with a hollow cavity 12a therein, a cover 14 that is configured to tightly mate with the housing 12, a scintillation detector or sensor 16 that includes, as shown in FIG. 4B and discussed in more detail below, a crystal CsI (Tl) of cesium iodide doped with thallium (hereinafter, may also be referred to as a “thallium doped cesium iodide,” “scintillation crystal CsI(Tl),” or “scintillator”). Also, as can be best seen in FIGS. 1, 2A, 3A and 3B, the radiation detector 10 includes, a digital display 18 having a screen or interface 20 adapted to fit within a display opening 22 of the cover 14, a radiation detector processing board 24, and operating buttons 26a and 26b adapted to fit within respective button openings 28a and 28b of the cover 14.

It will be understood that the radiation detector 10 is fully assembled when the housing 12 and cover 14 are securely connected with one another forming a shell or a shroud for the above-identified components arranged therein. As shown in FIG. 1, it is envisioned that the cavity 12a includes a battery 13, such as a rechargeable Li-poly battery.

With reference to FIGS. 4A-4D, the scintillation detector 16 includes a container 30, which can be made of a plastic or other suitable material, that comprises a holding cup 32 and a lid 34 that is configured to cover the holding cup 32 in a sufficiently tight and moisture-resistant manner. Optionally, the holding cup 32 may have a silicone gasket 36 to ensure sufficient protection from air and moisture when the lid 34 is connected with and covers the holding cup 32. As best seen in FIG. 4B, the holding cup is configured to receive and support therein a scintillation crystal CsI(Tl) 38, which will be described in more detail below.

Continuing with FIGS. 4A-4D, the lid 34 includes a flexible printed circuit board (PCB) 40 inserted therethrough via a slot 35 of the lid 34, which can be sealed with heat-and moisture-resistant mastic during assembly. As best shown in FIGS. 4C and 4D, the flexible PCB 40 includes a front side 40a and a back side 40b. The flexible PCB further includes a reinforcing member 42, shown in FIG. 4C, which can be made of steel or other suitable material. The back side 40b of the flexible PCB 40 includes a double-sided tape 44, such as for example poron urethane foam tape, that is attached to the reinforcing member 42. A flexible stem 46 of the flexible PCB 40 is either made of or has light protective polyimide film applied thereto on both the front and back sides 40a, 40b of the flexible PCB 40.

The front side 40a of the flexible PCB 40, shown in FIG. 4D, includes a silicon photomultiplier (SiPM) 48 and a thermo-sensor 50, both attached to the reinforcing member 42. Also, the stem 46 of the flexible PCB 40 includes an edge connector 52 having exposed contacts on the front side 40a of the flexible PCB 40. It should be understood that, when the lid 34 covers the holding cup 32, the back side 40b of the flexible PCB 40 is firmly secured to an interior wall 34a of the lid 34 via the double-sided tape 44, as shown in FIG. 4B.

Turning now to FIG. 4B, the scintillation crystal CsI(Tl) 38, which in an exemplary embodiment configured as a cube, includes a top surface 38a and a bottom surface 38b. It should be apparent that, when the scintillation crystal CsI(Tl) 38 is inserted into the holding cup 32, the scintillation crystal CsI(Tl) 38 is inserted bottom surface 38 first. The top surface 38a includes a reflective film 54 having a generally central window 56 therethrough. The window 56 serves as an optical interface between the SiPM 48 and the scintillation crystal CsI(Tl) 38. It is contemplated within the scope of the present disclosure that an optical gel 58 is applied within the window 56 to facilitate an optical contact between the SiPM 48 and the scintillation crystal CsI(Tl) 38. It should be further understood that, when the lid 34 covers the holding cup 32, the SiPM 48 comes in contact, via the optical gel 58, with the scintillation crystal CsI(Tl) 38, as shown in FIG. 4B. It is also contemplated within the scope of the present disclosure that a GAGG(Ce) crystal can be used instead of the scintillation crystal CsI(Tl) 38.

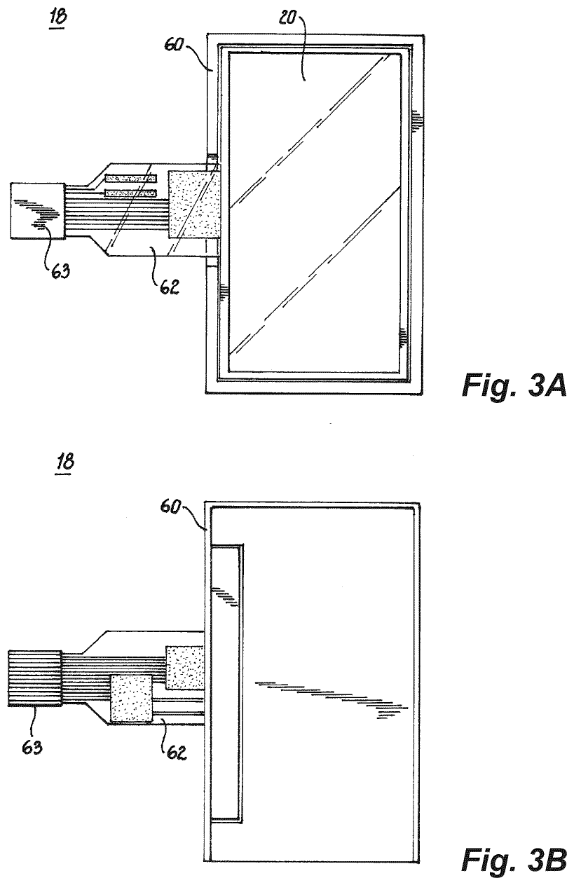

With reference to FIGS. 3A and 3B, the digital display 18, which is envisioned to be a clear, low-power backlit, monochrome graphical display that incorporates auditory, visual, and tactile alerts, includes a display frame 60 and a display flexible printed circuit board (PCB) 62, a first end of which is communicatively connected to the display frame 60. A second end of the display flexible PCB 62 includes a display connector 63. It will be noted that the digital frame 60 has a front side having the screen 20 attached thereto, as shown in FIG. 3A, and a back side, as shown in FIG. 3B.

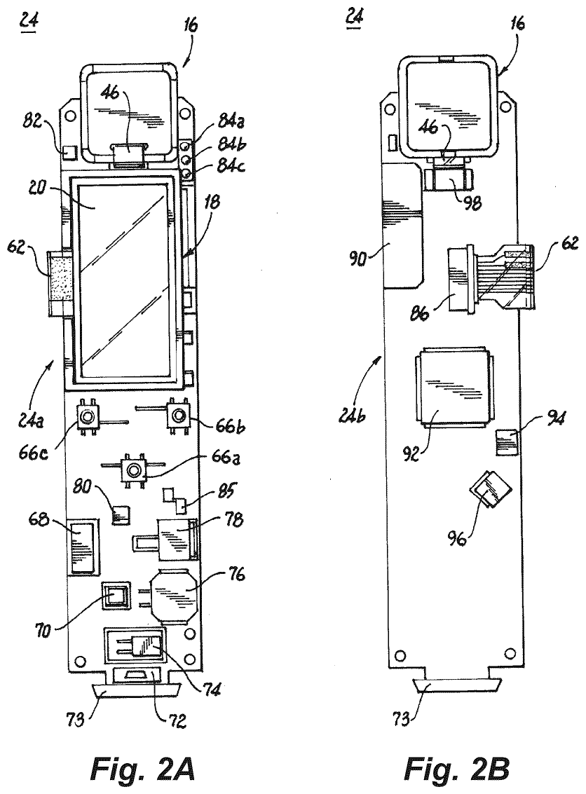

Turning now to FIGS. 2A and 2B, the radiation detector processing board 24 (hereinafter referred to as a processing board) includes a front side 24a, shown in FIG. 2A, and a back side 24b, shown in FIG. 2B. The front side 24a of the processing board 24 includes operating contacts 66a, 66b and 66c to be selectively activated by respective operating buttons 26a and 26b. The front side 24a of the processing board 24 further includes an antenna 68, such as for Bluetooth® connectivity, a battery charging Integrated Circuit (IC) 70, USB type C connector 72 for providing a wired connection to an external computing device (not shown), a vibration motor 74, a buzzer 76, and an Electrically Erasable Programmable Read-Only Memory (EEPROM) 78. The USB connector 72 may include a USB connector gasket 73 to protect the USB connector 72 from environmental elements when not in use.

The battery charging IC 70 is configured to charge the battery 13 from an energy source or the external computing device connected to the USB connector 72. The buzzer 76 is configured to produce a sound signal for the following actions: switching the device on and off, pressing one of the operating buttons 26a or 26b, establishing communication via Bluetooth, registration of radiation quantum, exceeding alarm thresholds, low battery warning, response to a “Search for device” request or other requests by a user (not shown) of the radiation detector 10.

Additionally, the front side 24a of the processing board 24 includes a precision temperature-compensated power supply 80, a photosensor 82, which is an ambient light sensor for enabling screen backlight in low-light conditions, and light indicators 84a-84c, such as a green LED 84a, a red LED 84b, and a blue LED 84c. These light indicators, when activated, are visible to the user through openings 15 in the cover 14. The green LED 84a is for gamma quantum detection (normal condition), the red LED 84b is for gamma quantum detection (alarm threshold is exceeded), and the blue LED 84c is for the status of the built-in battery 13.

The back side 24a of the processing board 24 includes a Zero-Insertion Force (ZIF) connector 86, an accelerometer 88, which is configured to control automatic display orientation when the radiation detector 10 is rotated, a peak detector 90, a microcontroller 92, a battery connector 94 configured to connect the battery 13 to the processing board 24, a Bluetooth® Integrated circuit (IC) 96, and a pulse amplitude detector 98. It should be noted that EEPROM 78 is used as an extra storage memory for when the microcontroller 92 (containing flash and RAM memories) does not have enough storage for data collected by the radiation detector 10. The data is stored until a remote computing device (not shown) is connected to the radiation detector 10. Once connected, a suitable app running on the remote computing device is configured to pull the data from the radiation detector 10 onto the remote computing device. The app is configured to pull the data in two ways: wireless Bluetooth® interface or wired USB interface. It should be further noted that the antenna 68 and Bluetooth IC 96 are configured to provide wireless connection between the radiation detector 10 and a remote computing device.

It should be understood that the vibration motor 74 is controlled by the microcontroller 92 and is configured to send one or more vibration signals indicating to the user of the radiation detector 10 when radiation levels or thresholds are exceeded, when operating buttons 26a/26b are pressed, when the radiation detector 10 is turned on/off, and also in response to a “Search for device” request.

As can be seen in FIGS. 2A and 2B, the digital display 18 is connected to the front side 24a of the processing board 24 while the display flexible PCB 62 wraps around to the back side 24b of the processing board 24 such that the display connector 63 is received by the ZIF connector 86 to communicatively connect the digital display 18 to the processing board 24. The scintillation detector 16 is also connected to the processing board 24 by a cavity 17 (FIG. 1) in the processing board 24 securely receiving the scintillation detector 16 while the flexible stem 46 of the flexible PCB 40 is fed through the processing board 24 allowing the edge connector 52 of the flexible PCB 40 to be inserted into the pulse amplitude detector 98 disposed on the back side 24b of the processing board 24.

Since radiation sensitivity of a scintillation crystal depends on its shape, it is contemplated that the scintillation crystal CsI(Tl) 38, which can be artificially grown to provide fluorescence spectrum with maximum at 550 nm, is formed as a cube to provide equivalent sensitivity to radiation in all directions and allows the radiation detector 10 to operate without a high-voltage power supply. The silicon photomultiplier (SiPM) 48 is envisioned as a semiconductor photomultiplier tube, which is a low-noise, high gain, UV-to-visible light and single-photon-sensitive sensor based on single-photon avalanche diodes (SPADs) implemented on a silicon substrate. The SiPM 48 has a low dark-count rate combined with a high PDE. For ultrafast timing applications, the SiPM 48 has a fast output that can have a rise time of 300 ps and a pulse width of 600 ps. The SiPM 48 can have different sizes (1 mm, 3 mm and 6 mm) and have a low operating voltage, excellent temperature stability, robustness, low cost, compactness, and output uniformity.

The peak detector 90 is configured for processing pulses received from the SiPM 48. The precision temperature-compensated power supply 80 for the SiPM 48 is part of a schematic solution of the radiation detector 10 and includes a number of Integrated Circuits (ICs) 85 and passive components. The power supply is implemented on several ICs and a number of passive components (resistors, capacitors) that are part of the circuit diagram of the radiation detector 10.

The microcontroller 92 includes a charge-voltage converter (not shown) and a 12-bit analog-to-digital converter (not shown) built into the microcontroller 92. The peak detector 90 includes a pulse amplitude detector 98 and a sample-and-hold circuit (not shown). The pulse amplitude detector 98 is configured to determine the moment in time corresponding to the top of the SiPM pulse. When the pulse amplitude detector 98 detects the top of the PMT pulse, the pulse amplitude detector 98 is configured to generate a control signal, according to which the sample-hold circuit switches from a tracking mode to a storage mode, and the microcontroller 92 activates and begins the amplitude digitization cycle, discussed in more detail below.

The pulse amplitude detector 98 is configured to analyze the shape of the pulse coming from the SiPM 48. At the moment when the pulse reaches its maximum value, a special circuit (not shown) generates a control signal that begins the ADC conversion cycle, which is approximately 4 microseconds. The results of the conversion are stored in the RAM of the microcontroller 92 for future analysis by a digital signal processing algorithm. After completing the cycle, the circuit goes into the initial state of waiting for the next pulse.

The microcontroller 92, which has an embedded flash memory configured to store firmware, performs the functions of controlling the processing board 24 and analog-to-digital voltage conversion from the output of the sample-hold circuit corresponding to the PM pulse amplitude. The microcontroller 92 that is configured to execute an adaptive processing algorithm/computer-readable instructions stored in the flash memory provides the radiation detector 10 with the capacity to (a) have high sensitivity to gamma and x-ray radiation, (b) count the number of pulses (radioactive decays), (c) take into account the amplitude of the pulses, (d) estimate the radiation dose equivalent to the human body, (e) display the shape of the energy spectrum of ionizing radiation, (f) evaluate the random error of the dose and dose rate estimates, and (g) provide instant notification of radiation hazard to the user.

To achieve reliable and high-quality detection of SiPM pulses, on the one hand, a sufficiently high speed of analog conversion elements is required. On the other hand, it is necessary to ensure low power consumption of these elements. Since an increase in performance causes an increase in power consumption, a contradiction arises between these two requirements. The resulting compromise solution provides the following characteristics:
bandwidth of analog processing circuits is at least 10 MHz;
total static consumption of analog processing circuits is no more than 2.1 mW;
pulse detection time from 1 to 1.5μs;
pulse digitization cycle duration 4μs;
average dead time 5μs.

In operation, the radiation detector 10 detects and measures radiation according to the following steps: whenever ionizing radiation enters the scintillation crystal CsI(Tl) 38, an ionization is produced within the scintillator 38. Subsequent to the ionization, a glow or scintillation in the optical range is formed in the scintillation crystal CsI(Tl) 38. The glow emits light, which is collected by the silicon photomultiplier (SiPM) 48 installed on the top surface 38a of the scintillation crystal CsI(Tl) 38, as shown in FIG. 4B. To ensure maximum light collection by the SiPM 48, every other surface or facet of the scintillator 38, except the top surface 38a, is preferably covered with the reflective film 54. The SiPM 48 includes a photocathode end, which is configured, as a result of the photoelectric effect, to convert the light into a stream of electrons. The resulting SiPM anode current signal is fed to an analog signal amplifier circuit and then to an analog-to-digital converter controlled by the microprocessor 92. The software built into the microprocessor 95 (firmware) of the radiation detector 10 conducts a digital signal processing resulting in a stream of digital data. The digital data obtained by way of the digital signal processing is the value proportional to the energy of ionizing particles that entered the scintillation crystal 38. This data is further used by the firmware to calculate dose rates and plot spectra, display these results on the screen 20 of the digital display 18, and transmit these results externally via wired or wireless interfaces.

The radiation detector 10, having the thallium doped cesium iodide crystal 38, which was optimized in shape and size, the solid-state photomultiplier 48, and customized analog-digital processing, provides the radiation detector 10 a high radiation sensitivity in a wide range of ionizing radiation energies and in all around directions. Non-limiting examples of the key features of the radiation detector 10 of the present disclosure include:
instant response to changes in radiation levels, approx. 30x times faster than regular Geiger counters, based on GM tubes;
binding the measurement results to the coordinates of the area with their display on Google maps (when working with a smartphone);
visualization of the energy spectrum of the absorbed radiation;
identification of the types of isotopes;
measurement in units convenient for you: sievert (Sv), impulse/sec (CPS), impulse/min (CPM), roentgens (R);
wireless communication with a smartphone on Android and iOS;
long-term autonomous work-up to 300 hours in the active mode;
auto backlight display in the dark;
auto-rotation of the screen image when the device is turned over;
a huge amount of built-in memory (32 MB or up to 1000 hours of observation);
increased splash and dust protection of the case (class IP64);
an indication of the current error of the result (to understand the level of its accuracy);
the dosimeter is easy to charge just like a cell phone;
independent update of the device firmware;
USB connection to PC for full-fledged work with the dosimeter;
quick search for radiation sources;
display of measurement results in the form of accumulated dose, dose rate, count rate;
dose rate and counting rate are additionally displayed graphically;
alarm signaling when the set thresholds are exceeded (light, sound, and vibration);
an indication of the current level of error of the displayed measurement result;
the ability to transfer the received data not only to a computer and smartphone, but

also to store it in external cloud storage.

Accordingly, the multifunctional radiation detector 10 of the present disclosure is configured to detect Gamma, high energy Beta, and continuous X-rays in the energy range of 0.05 . . . 3.0 MeV and in the power range of 0.1-1'000μSv/h, as well as assess the ambient background radiation and the level of radiation from various substances and objects.

Changes and modifications in the specifically described embodiments may be carried out without departing from the principles of the present invention, which is intended to be limited only by the scope of the appended claims, as interpreted according to the principles of patent law including the doctrine of equivalents.

1. A radiation detector comprising:
a housing having a hollow interior, a display opening and one or more secondary openings; and
a processing board enclosed within the interior of the housing and comprising:
a scintillation detector including a cube-shaped scintillation crystal and a flexible printed circuit board (PCB), wherein a first end of the flexible PCB includes a solid-state silicon photomultiplier that is optically connected to the scintillation crystal, and wherein a second end of the flexible PCB is communicatively connected to the processing board;
a microprocessor configured to process electrical pulses received from the silicon photomultiplier and output a value that is proportional to an energy of ionizing particles detected by the scintillation crystal;
a display having a display flexible PCB communicatively connected to the processing board, the display is configured to be received within the display opening of the housing; and
one or more operating buttons for selectively operating the radiation detector, the one or more operating buttons are configured to be received within respective one or more secondary openings in the housing;
wherein the radiation detector is configured to detect, analyze and measure a broad spectrum of ionizing radiation energies.

2. The radiation detector of claim 1, wherein the scintillation detector comprises a cube-shaped container having a holding cup for supporting the scintillation crystal therein and a lid for covering the holding cup, the lid having a slot for receiving the flexible PCB therethrough, and wherein the scintillation crystal is a crystal CsI (Tl) of cesium iodide doped with thallium.

3. The radiation detector of claim 2, wherein the first end of the flexible PCB includes a reinforcing member having two opposing sides, wherein a first side of the two opposing sides includes an attachment member for attaching the reinforcing member to the lid of the scintillation detector, and wherein a second side of the two opposing sides includes the solid-state silicon photomultiplier and a thermo-sensor.

4. The radiation detector of claim 3, wherein the scintillation crystal is covered in a reflective film, the reflective film having a window therethrough, and wherein the silicon photomultiplier, when the lid of the container covers the holding cup, contacts the scintillation crystal via an optical interface.

5. The radiation detector of claim 1, wherein the silicon photomultiplier, when the scintillation crystal is exposed to an ionizing radiation energy, is configured to convert light emitted from the scintillation crystal into a stream of electrons.

6. The radiation detector of claim 1, further comprising:
a rechargeable battery, wherein the processing board includes a battery charging integrated circuit configured to electrically charge the battery from an energy source and a battery connector configured to connect the battery to the processing board.

7. The radiation detector of claim 1, wherein the processing board includes an antenna, a USB connector, a vibration motor configured to generate a vibration signal, and a buzzer for producing a sound signal.

8. The radiation detector of claim 1, wherein the processing board includes an electrically erasable programmable read-only memory (EEPROM) configured as an extra storage memory, a precision temperature-compensated power supply, a photosensor, and a plurality of light indicators.

9. The radiation detector of claim 1, wherein the processing board includes a zero-insertion force connector for receiving the display flexible PCB of the display and an accelerometer configured to control the display orientation when the radiation detector is rotated.

10. The radiation detector of claim 1, wherein the processing board includes a peak detector, a Bluetooth integrated circuit, and a pulse amplitude detector configured to receive the second end of the flexible PCB of the scintillation detector.

11. The radiation detector of claim 1, wherein the microprocessor includes an embedded flash memory configured to store firmware and is configured to execute an adaptive processing algorithm or computer-readable instructions stored in the flash memory.

12. A radiation detector having a housing with a hollow interior, a display opening and one or more secondary openings, and a processing board enclosed within the interior of the housing, the radiation detector comprising:
a scintillation detector including a cube-shaped scintillation crystal and a flexible printed circuit board (PCB), wherein a first end of the flexible PCB includes a reinforcing member having two opposing sides, a first side of the two opposing sides includes an attachment member and a second side of the two opposing sides includes a solid-state silicon photomultiplier and a thermo-sensor, the silicon photomultiplier is optically connected to the scintillation crystal, and wherein a second end of the flexible PCB is communicatively connected to the processing board;
a microprocessor having an embedded flash memory with firmware and computer-readable instructions stored thereon, the microprocessor is configured to process electrical pulses received from the silicon photomultiplier and calculate a value that is proportional to an energy of ionizing particles detected by the scintillation crystal;
a display having a display flexible PCB communicatively connected to the processing board, the display is configured to be received within the display opening of the housing and configured to display the value calculated by the microprocessor; and
one or more operating buttons for selectively operating the radiation detector, the one or more operating buttons are configured to be received within respective one or more secondary openings in the housing;
wherein the radiation detector is configured to detect, analyze and measure a broad spectrum of ionizing radiation energies.

13. The radiation detector of claim 12, wherein the scintillation detector comprises a cube-shaped container having a holding cup for supporting the scintillation crystal therein and a lid for covering the holding cup, the lid having a slot for receiving the flexible PCB therethrough, and wherein the scintillation crystal is a crystal CsI (Tl) of cesium iodide doped with thallium.

14. The radiation detector of claim 13, wherein the attachment member is a double-sided adhesive that, when the lid covers the holding cup of the container, attaches the reinforcing member to the lid of the scintillation detector.

15. The radiation detector of claim 14, wherein the scintillation crystal is covered in a reflective film, the reflective film having a window therethrough, and wherein the silicon photomultiplier, when the lid of the container covers the holding cup, contacts the scintillation crystal via an optical gel.

16. The radiation detector of claim 12, wherein the silicon photomultiplier, when the scintillation crystal is exposed to an ionizing radiation energy, is configured to convert light emitted from the scintillation crystal into a stream of electrons.

17. The radiation detector of claim 12, further comprising:
a rechargeable battery, wherein the processing board includes a battery charging integrated circuit configured to electrically charge the battery from an energy source and a battery connector configured to connect the battery to the processing board.

18. The radiation detector of claim 12, wherein the processing board includes an antenna, a USB connector, a vibration motor configured to generate a vibration signal, and a buzzer for producing a sound signal.

19. The radiation detector of claim 12, wherein the processing board includes an electrically erasable programmable read-only memory (EEPROM) configured as an extra storage memory, a precision temperature-compensated power supply, a photosensor, and a plurality of light indicators.

20. The radiation detector of claim 12, wherein the processing board includes a zero-insertion force connector for receiving the display flexible PCB of the display, an accelerometer configured to control the display orientation when the radiation detector is rotated, a peak detector, a Bluetooth integrated circuit, and a pulse amplitude detector configured to receive the second end of the flexible PCB of the scintillation detector.
